(19) United States
(12) Patent Application Publication
(10) Pub. No.: US 2026/0019060 A1
(43) Pub. Date: Jan. 15, 2026

(54) ACOUSTIC WAVE DEVICE, ACOUSTIC WAVE MODULE, FILTER DEVICE, MULTIPLEXER, AND COMMUNICATION APPARATUS

(71) Applicant: Murata Manufacturing Co., Ltd., Nagaokakyo-shi (JP)

(72) Inventor: Koji NOSAKA, Nagaokakyo-shi (JP)

(21) Appl. No.: 19/338,083

(22) Filed: Sep. 24, 2025

Related U.S. Application Data
(63) Continuation of application No. PCT/JP2024/011567, filed on Mar. 25, 2024.

(30) Foreign Application Priority Data
May 24, 2023 (JP) 2023-085359

(51) Int. Cl. H03H 9/02; H03H 9/05; H03H 9/25; H03H 9/64

(52) U.S. Cl. CPC H03H 9/02818; H03H 9/058; H03H 9/25; H03H 9/6483

(57) ABSTRACT

An acoustic wave device includes a piezoelectric substrate including a first main surface, first and second connection terminals, and a first grounding terminal on the first main surface, functional elements on the first main surface, a first shield electrode on the first main surface and connected to the first grounding terminal, a support on the first main surface around a region in which the first and second connection terminals, the first grounding terminal, the functional elements, and the first shield electrode are located, and a cover supported by the support and located opposite to the piezoelectric substrate. The support includes metal. The piezoelectric substrate, the support, and the cover define a hollow space, and the first shield electrode is located between the first connection terminal and a portion of the support located at a position closest to the first connection terminal, on the first main surface in plan view.

### CROSS REFERENCE TO RELATED APPLICATIONS

This application claims the benefit of priority to Japanese Patent Application No. 2023-085359 filed on May 24, 2023 and is a Continuation Application of PCT Application No. PCT/JP2024/011567 filed on Mar. 25, 2024. The entire contents of each application are hereby incorporated herein by reference.

### BACKGROUND OF THE INVENTION

### 1. Field of the Invention

The present invention relates to acoustic wave modules each including an acoustic wave device, and more particularly to package structures of acoustic wave modules that each reduce or prevent a decrease in isolation between an input and an output.

### 2. Description of the Related Art

Electronic devices such as mobile phones or smartphones include acoustic wave modules including acoustic wave devices in which surface acoustic wave (SAW) or bulk acoustic wave (BAW) resonators are used. In an acoustic wave device having a typical wafer level package (WLP) structure, a piezoelectric substrate, a support disposed on the surface of the piezoelectric substrate so as to surround the substrate, and a cover disposed above the support form a hollow space, and input/output terminals, grounding terminal, and a functional element are disposed on the surface of the piezoelectric substrate in the hollow space.

Japanese Unexamined Patent Application Publication No. 2013-90228 discloses an acoustic wave device including a piezoelectric substrate having a groove in which a support is disposed thus reducing moisture that enters a hollow space from the outside. Japanese Unexamined Patent Application Publication No. 2013-90228 describes that the support is made of metal.

In general, airtightness of a hollow space is better when a support is made of metal than when a support is made of resin. However, a support made of metal is conductive and thus may generate capacitive coupling with input/output terminals disposed in the hollow space, and this capacitive coupling may reduce the isolation between an input and an output.

### SUMMARY OF THE INVENTION

Example embodiments of the present invention reduce or prevent a decrease in isolation between an input and an output of acoustic wave devices having a WLP structure in which a support is made of metal.

An acoustic wave device according to an example embodiment of the present invention includes a piezoelectric substrate including a first main surface, a first connection terminal, a second connection terminal, and a first grounding terminal on the first main surface, a functional element on the first main surface and configured to excite an acoustic wave to transmit a signal from the first connection terminal to the second connection terminal, a first shield electrode on the first main surface and connected to the first grounding terminal, a support on the first main surface around a region in which the first connection terminal, the second connection terminal, the first grounding terminal, the functional element, and the first shield electrode are located, and with a thickness in a direction normal to the first main surface, and a cover supported by the support and located opposite to the piezoelectric substrate. The support is made of metal, the piezoelectric substrate, the support, and the cover define a hollow space, and the first connection terminal, the second connection terminal, the first grounding terminal, the functional element, and the first shield electrode are located in the hollow space, and the first shield electrode is located between the first connection terminal and a portion of the support, the portion being located at a position closest to the first connection terminal, on the first main surface in plan view.

According to example embodiments of the present invention, in acoustic wave devices each having a WLP structure including a support made of metal, a shield electrode is located between the support and input/output terminals to block capacitive coupling between the support and the input/output terminals. This arrangement reduces or prevents a decrease in isolation between an input and an output of the acoustic wave device having a WLP structure including a support made of metal.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1 is a circuit block diagram of a multiplexer according to Example Embodiment 1 of the present invention.

FIG. 2 is a diagram illustrating a circuit configuration of a filter according to Example Embodiment 1 of the present invention.

FIG. 3 is a cross-sectional view of an acoustic wave module including an acoustic wave device according to Example Embodiment 1 of the present invention.

FIG. 4 is a plan view of the acoustic wave module taken along line I-I of FIG. 3.

FIG. 5 is a plan view of a cover taken along line II-II of FIG. 3.

FIG. 6 is a diagram illustrating a first layer of a mounting board according to Example Embodiment 1 of the present invention as viewed from the positive side of the Z axis.

FIG. 7 is a diagram illustrating a second layer of the mounting board according to Example Embodiment 1 of the present invention as viewed from the positive side of the Z axis.

FIG. 8 is a diagram illustrating a third layer of the mounting board according to Example Embodiment 1 of the present invention as viewed from the positive side of the Z axis.

FIG. 9 is a plan view of a piezoelectric substrate according to Comparative Example 1.

FIG. 10 is a diagram illustrating a circuit configuration of an acoustic wave device according to Comparative Example 1.

FIG. 11 is a first diagram for comparing the isolation between connection terminals of acoustic wave devices.

FIG. 12 is a first diagram for comparing the filter characteristics of acoustic wave devices.

FIG. 13 is a diagram illustrating a circuit configuration of an acoustic wave device according to Comparative Example 3.

FIG. 14 is a second diagram for comparing the filter characteristics of acoustic wave devices.

FIG. 15 is a third diagram for comparing the filter characteristics of acoustic wave devices.

FIG. 16 is a plan view of a cover according to Modification 1 of an example embodiment of the present invention.

FIG. 17 is a fourth diagram for comparing the filter characteristics of acoustic wave devices.

FIG. 18 is an enlarged view of a region in FIG. 17.

FIG. 19 is a plan view of a piezoelectric substrate according to Modification 2 of an example embodiment of the present invention.

FIG. 20 is a cross-sectional view of an acoustic wave module including an acoustic wave device according to Modification 3 of an example embodiment of the present invention.

FIG. 21 is a fifth diagram for comparing the filter characteristics of acoustic wave devices.

FIG. 22 is a block diagram of a communication apparatus according to Modification 4 of an example embodiment of the present invention.

FIG. 23 is a plan view of a piezoelectric substrate according to Embodiment 2 of the present invention.

FIG. 24 is a diagram illustrating a circuit configuration of an acoustic wave device according to Example Embodiment 2 of the present invention.

FIG. 25 is a sixth diagram for comparing the filter characteristics of acoustic wave devices.

FIG. 26 is a seventh diagram for comparing the filter characteristics of acoustic wave devices.

FIG. 27 is a second diagram for comparing the isolation between connection terminals.

### DETAILED DESCRIPTION OF THE EXAMPLE EMBODIMENTS

Hereinafter, example embodiments of the present invention will be described in detail with reference to the drawings. The same or corresponding portions in the figures are assigned the same symbols, and their descriptions will not be repeated.

### Example Embodiment 1

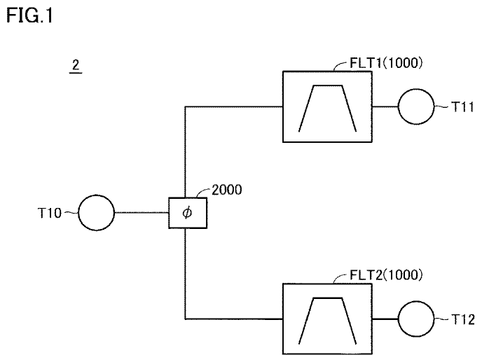

FIG. 1 is a circuit block diagram of a multiplexer 2 according to Example Embodiment 1 of the present invention. As illustrated in FIG. 1, the multiplexer 2 includes a common terminal T10, input/output terminals T11 and T12, filters FLT1 and FLT2, and a phase shifter 2000. The filters FLT1 and FLT2 each include an acoustic wave module 1000 including an acoustic wave device 110 according to Example Embodiment 1, and are configured to pass transmission signals in their respective pass bands.

The multiplexer 2 allows a signal in a first pass band that is input to the common terminal T10 to be output from the input/output terminal T11, and a signal in a second pass band that is input to the common terminal T10 to be output from the input/output terminal T12. A signal in the first pass band that is input from the input/output terminal T11 is output from the common terminal T10, and a signal in the second pass band that is input from the input/output terminal T12 is output from the common terminal T10. In the present example embodiment, the first pass band is, for example, the n77 band (about 3.3 GHZ to about 4.2 GHz), and the second pass band is, for example, the n79 band (about 4.4 GHz to about 5.0 GHZ). In other words, the first pass band and the second pass band do not overlap each other. The first pass band and the second pass band may be other frequency bands as long as they do not overlap each other.

The filter FLT1 is connected between the phase shifter 2000 and the input/output terminal T11. The phase shifter 2000 increases the impedance of the filter FLT1 in the second pass band to reduce or prevent transmission of a signal in the second pass band from the common terminal T10 to the filter FLT1 and improve transmission of the signal to the filter FLT2. The filter FLT2 is connected between the input/output terminal T12 and the phase shifter 2000. In the following description, an acoustic wave resonator is assumed to be an ideal element that does not have a resistive component. In the following description, the filters FLT1 and FLT2 may be collectively referred to as a “filter FLT”.

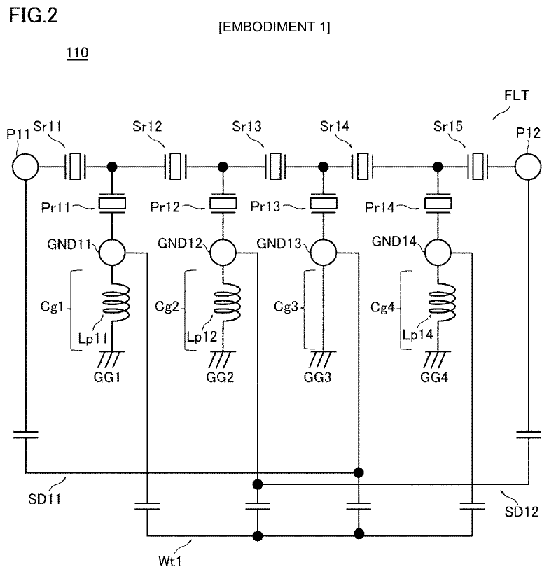

FIG. 2 is a diagram illustrating a circuit configuration of a filter FLT according to Example Embodiment 1. The filter FLT is a ladder filter connected between a connection terminal P11 and a connection terminal P12. For example, the filter FLT filters a signal received at the connection terminal P11 and outputs the signal from the connection terminal P12.

The acoustic wave device 110 defining and functioning as the filter FLT includes a series-arm circuit including series-arm resonators Sr11 to Sr15 connected in series between the connection terminal P11 and the connection terminal P12, and a parallel-arm circuit including parallel-arm resonators Pr11 to Pr14 connected between the series-arm circuit and ground electrodes GG1 to GG4.

One end of the parallel-arm resonator Pr11 is connected to the connection point between the series-arm resonator Sr11 and the series-arm resonator Sr12, and the other end is connected to the ground electrode GG1 via a ground terminal GND11 and an inductor Lp11. One end of the parallel-arm resonator Pr12 is connected to the connection point between the series-arm resonator Sr12 and the series-arm resonator Sr13, and the other end is connected to the ground electrode GG2 via a ground terminal GND12 and an inductor Lp12.

One end of the parallel-arm resonator Pr13 is connected to the connection point between the series-arm resonator Sr13 and the series-arm resonator Sr14, and the other end is connected to the ground electrode GG3 via a ground terminal GND13. One end of the parallel-arm resonator Pr14 is connected to the connection point between the series-arm resonator Sr14 and the series-arm resonator Sr15, and the other end is connected to the ground electrode GG4 via a ground terminal GND14 and an inductor Lp14.

As illustrated in FIG. 2, the acoustic wave device 110 according to Example Embodiment 1 includes a shield electrode SD11 that is capacitively coupled to the connection terminal P11. The acoustic wave device 110 according to Example Embodiment 1 also includes a support electrode Wt1 that is capacitively coupled to the shield electrode SD11. The shield electrode SD11 is connected to the ground terminal GND13. The acoustic wave device 110 according to Example Embodiment 1 also includes a shield electrode SD12 that is capacitively coupled to the connection terminal P12. The shield electrode SD12 is capacitively coupled to the support electrode Wt1 as is the shield electrode SD11. The shield electrode SD12 is connected to the ground terminal GND12. As illustrated in FIG. 2, the support electrode Wt1 is capacitively coupled to the ground terminals GND11 and GND14. That is, the support electrode Wt1 is capacitively coupled to the shield electrodes SD11 and SD12 and the ground terminals GND11 and GND14. In FIG. 2, an inductive component of the support electrode Wt1 is not depicted.

A wiring structure Cg1 is disposed between the ground terminal GND11 and the ground electrode GG1, and includes the inductor Lp11. A wiring structure Cg2 is disposed between the ground terminal GND12 and the ground electrode GG2, and includes the inductor Lp12. A wiring structure Cg3 is disposed between the ground terminal GND13 and the ground electrode GG3. A wiring structure Cg4 is disposed between the ground terminal GND14 and the ground electrode GG4, and includes the inductor Lp14. That is, the wiring structures Cg1 to Cg4 are each a path including a plurality of components such as a via, an electrode, and a trace.

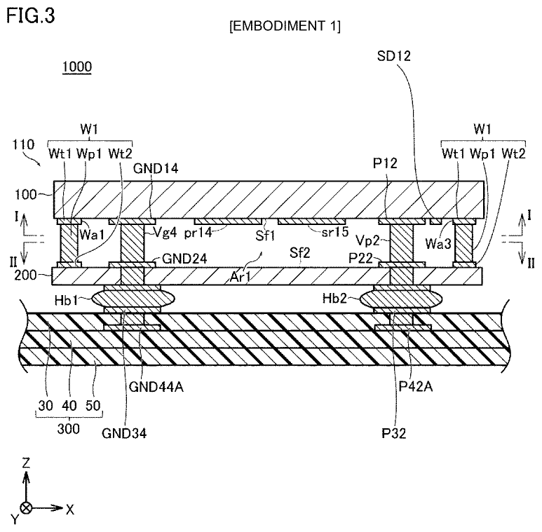

A structure of the acoustic wave module 1000 including the acoustic wave device 110 according to Example Embodiment 1 will be described below. With reference to FIGS. 3 to 8, description will be provided below with regard to the acoustic wave module 1000 according to Example Embodiment 1 in which inductance values of the wiring structures Cg1 to Cg4 are individually set to allow a signal in the first pass band (n77 band) to transmit.

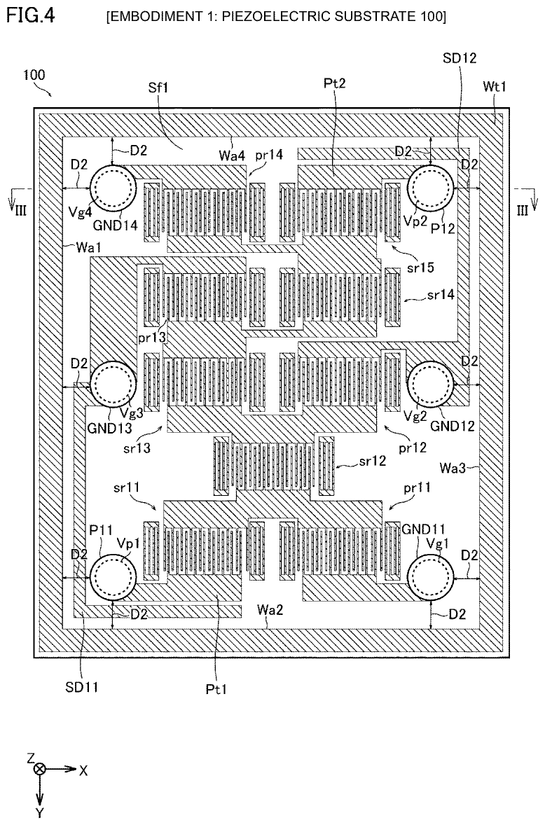

FIG. 3 is a cross-sectional view of the acoustic wave module 1000 including the acoustic wave device 110 according to Example Embodiment 1. FIG. 4 is a plan view of the acoustic wave module 1000 taken along line I-I of FIG. 3. The cross-sectional view of the acoustic wave module 1000 illustrated in FIG. 3 is taken along line III-III of FIG. 4. Although the acoustic wave device 110 in Example Embodiment 1 is described as a surface acoustic wave device including an IDT electrode as a functional element, a component such as, for example, a bulk acoustic wave resonator can also be used. In another example, a bulk acoustic wave resonator to be used may be, for example, a film bulk acoustic resonator (FBAR), a solid mounted resonator (SMR), or a transversely-excited film bulk acoustic resonator (XBAR).

With reference to FIG. 3, the acoustic wave module 1000 includes the acoustic wave device 110 and a mounting board 300 to which the acoustic wave device 110 is mounted. As illustrated in FIG. 3, the acoustic wave device 110 includes a piezoelectric substrate 100, a support W1, a cover 200, functional elements pr14 and sr15, ground terminals GND14 and GND24, connection terminals P12 and P22, and columnar electrodes Vg4 and Vp2.

In the following description, the Z-axis direction is defined as the thickness direction of the piezoelectric substrate 100, and the X axis and the Y axis are defined in a plane perpendicular or substantially perpendicular to the Z-axis direction. The positive direction of the Z axis in the figures may be referred to as the upper surface side, and the negative direction may be referred to as the lower surface side. In other words, the negative direction of the Z axis is a direction perpendicular or substantially perpendicular (normal) to the surface of the piezoelectric substrate 100.

The acoustic wave device 110 and the mounting board 300 are connected to each other via solder bumps Hb1 and Hb2. Each of the solder bumps Hb1 and Hb2 may correspond to a “connection component” in the present disclosure. The mounting board 300 includes a layer 30, a layer 40, and a layer 50. As illustrated in FIG. 3, the layers are arranged in the order of the layer 30, the layer 40, and the layer 50 from the positive side of the Z axis. The layer 30 includes a connection terminal P32 and a ground terminal GND34, and the layer 40 includes a connection terminal P42A and a ground terminal GND44A. The internal structures of the layer 30 to the layer 50 will be described in detail below.

The mounting board 300 is made of resin such as phenol or epoxy, for example. The mounting board 300 may be made of ceramics such as alumina or low temperature co-fired ceramics (LTCC), or resin such as glass epoxy or liquid crystal polymer, for example.

The piezoelectric substrate 100 includes a main surface Sf1. The main surface Sf1 may correspond to a “first main surface” in the present disclosure. The piezoelectric substrate 100 is made of piezoelectric material such as, for example, aluminum nitride (AlN), lithium tantalate (LiTaO₃), lithium niobate (LiNbO₃), or aluminum nitride doped with scandium (Sc) or ytterbium (Yb). The piezoelectric substrate 100 may be a laminated substrate in which a piezoelectric thin film made of the above-described piezoelectric material is laminated on a substrate made of alumina, silicon (Si), quartz crystal, or sapphire, for example. The piezoelectric substrate 100 may also be a laminated substrate in which one or more insulating layers made of material such as, for example, silicon oxide or silicon nitride are sandwiched between the piezoelectric thin film and the substrate.

At least one functional element is disposed on the main surface Sf1 of the piezoelectric substrate 100. FIG. 4 illustrates a plan view of the main surface Sf1 as viewed from the negative side of the Z axis. As illustrated in FIG. 4, the acoustic wave device 110 includes functional elements pr11 to pr13 and sr11 to sr14 on the main surface Sf1, as well as the functional elements pr14 and sr15 illustrated in FIG. 3. The functional elements sr11 to sr15 correspond to the series-arm resonators Sr11 to Sr15, respectively, illustrated in FIG. 2. The functional elements pr11 to pr14 correspond to the parallel-arm resonators Pr11 to Pr14, respectively, illustrated in FIG. 2.

As illustrated in FIG. 4, the acoustic wave device 110 includes a connection terminal P11 on the main surface Sf1 as well as the connection terminal P12 illustrated in FIG. 3. The acoustic wave device 110 also includes ground terminals GND11 to GND13 as well as the ground terminal GND14 illustrated in FIG. 3. The acoustic wave device 110 also includes the support electrode Wt1 on the main surface Sf1. The support electrode Wt1 is a portion of the support W1.

As illustrated in FIG. 3, the support W1 includes support electrodes Wt1 and Wt2 and a support wall Wp1. In summary, the functional elements pr11 to pr14 and sr11 to sr15, the connection terminals P11 and P12, the ground terminals GND11 to GND14, and the support electrode Wt1 are disposed on the main surface Sf1. The shield electrodes SD11 and SD12, which will be described below, are also disposed on the main surface Sf1.

The connection terminal P11 may correspond to a “first connection terminal” in the present disclosure. The connection terminal P12 may correspond to a “second connection terminal” in the present disclosure. The ground terminal GND13 may correspond to a “first grounding terminal” in the present disclosure. The ground terminal GND12 may correspond to a “second grounding terminal” in the present disclosure. Each of the ground terminals GND11 and GND14 may correspond to a “fourth grounding terminal” in the present disclosure.

The functional elements pr11 to pr14 and sr11 to sr15 illustrated in FIG. 4 are each a pair of IDT electrodes. The piezoelectric substrate 100 and IDT electrodes define a surface acoustic wave resonator. As illustrated in FIG. 4, the support electrode Wt1 is disposed around a region in which the connection terminals P11 and P12, the ground terminals GND11 to GND14, and the functional elements pr11 to pr14 and sr11 to sr15 are disposed on the piezoelectric substrate 100. With reference to FIG. 4, the support electrode Wt1 according to Example Embodiment 1 has a rectangular or substantially rectangular frame shape and supports the cover 200. The support wall Wp1 and the support electrode Wt2 also have a rectangular or substantially rectangular frame shape and support the cover 200, as the support electrode Wt1 does. The shapes of the support electrode Wt1, the support wall Wp1, and the support electrode Wt2 are not limited to a rectangular or substantially rectangular frame shape. The support electrode Wt1, the support wall Wp1, and the support electrode Wt2 may have a frame shape capable of defining a hollow space Ar1. For example, the frame shape may be a rectangle with tapered corners, or may be an ellipse or a circle, when viewed from the positive side of the Z axis.

With reference to FIG. 3, the cover 200 includes a main surface Sf2. The main surface Sf2 faces the main surface Sf1. The main surface Sf2 may correspond to a “second main surface” in the present disclosure. The support electrode Wt2 is disposed on the main surface Sf2. In Example Embodiment 1, the main surface Sf2 of the cover 200 faces the main surface Sf1 of the piezoelectric substrate 100 with the support W1 interposed therebetween, thus defining the hollow space Ar1 around a plurality of functional elements including the IDT electrodes. This allows a surface acoustic wave to propagate in a portion of the piezoelectric substrate 100 adjacent to the hollow space Ar1.

The functional elements pr11 to pr14 and sr11 to sr15 are made of electrode material such as at least one elemental metal of, for example, aluminum, copper, silver, gold, titanium, tungsten, platinum, chromium, nickel, or molybdenum, or an alloy containing these elemental metals as its main component. The electrode material may be a laminated electrode including multiple layers of electrodes. The columnar electrodes Vg4 and Vp2, the ground terminals GND14 and GND24, and the connection terminals P12 and P22 are made of metal such as, for example, copper or aluminum.

As illustrated in FIG. 3, the support electrode Wt1 having a rectangular or substantially rectangular frame shape includes a surface Wa1 and a surface Wa3 that are exposed to the hollow space Ar1. As illustrated in FIG. 4, the support electrode Wt1 has a rectangular or substantially rectangular frame shape, and thus includes surfaces Wa2 and Wa4 as well as the surfaces Wa1 and Wa3. The surface Wa1 faces the surface Wa3. The surface Wa2 faces the surface Wa4. The surfaces Wa1, Wa2, Wa3, and Wa4 correspond to a “first surface,” a “second surface,” a “third surface,” and a “fourth surface,” respectively, in the present disclosure.

In Example Embodiment 1, each of the connection terminals P11 and P12 and each of the ground terminals GND11 to GND14 are disposed at a distance D2 from a corresponding one of the surfaces Wa1 to Wa4. In other words, a shortest distance from each of the connection terminals P11 and P12 and each of the ground terminals GND11 to GND14 to the support W1 having a frame shape is equal or substantially equal to the distance D2.

More specifically, in the X-axis direction illustrated in FIG. 4, the distance between the connection terminal P11 and the surface Wa1, the distance between the ground terminal GND13 and the surface Wa1, and the distance between the ground terminal GND14 and the surface Wa1 are each equal or substantially equal to the distance D2. In the X-axis direction, the distance between the connection terminal P12 and the surface Wa3, the distance between the ground terminal GND12 and the surface Wa3, and the distance between the ground terminal GND11 and the surface Wa3 are each also equal or substantially equal to the distance D2.

Furthermore, in the Y-axis direction illustrated in FIG. 4, the distance between the connection terminal P11 and the surface Wa2 and the distance between the ground terminal GND11 and the surface Wa2 are each also equal or substantially equal to the distance D2. In the Y-axis direction, the distance between the connection terminal P12 and the surface Wa4 and the distance between the ground terminal GND14 and the surface Wa4 are each also equal or substantially equal to the distance D2. In Example Embodiment 1, an example is described in which the distances from the ground terminals GND11 to GND14 to the support electrode Wt1 and the distances from the connection terminals P11 and P12 to the support electrode Wt1 are all equal or substantially equal to the same distance D2, but the distances from the ground terminals GND11 to GND14 to the support electrode Wt1 and the distances from the connection terminals P11 and P12 to the support electrode Wt1 may be different from each other.

In the acoustic wave module 1000 according to Embodiment 1, the support W1 is made of aluminum (Al), for example. The support W1 may be made of any metal, and in one example, may be a conductor such as copper (Cu), gold (Au), titanium (Ti), molybdenum (Mo), tungsten (W), platinum (Pt), ruthenium (Ru), nickel (Ni), or tantalum (Ta), or an alloy thereof.

In general, metals have higher airtightness and liquid-tightness than materials such as resin due to their structure. Thus, in Example Embodiment 1, the support W1, which is made of a high-density metal, is able to more effectively reduce moisture and the like entering the hollow space Ar1 from the outside than the support W1 made of resin. On the other hand, the support W1, which is made of metal, is conductive and may be capacitively coupled to the connection terminals P11 and P12 in the hollow space Ar1, leading to a decrease in the isolation between the input and the output as a result.

Thus, in Example Embodiment 1, as illustrated in FIGS. 2 and 4, the shield electrode SD11 connected to the ground terminal GND13 is disposed between the connection terminal P11 and the support electrode Wt1. The shield electrode SD11 has an L shape that extends from the ground terminal GND13 toward the positive side of the Y axis, then bends about 90 degrees to extend toward the positive side of the X axis. The shield electrode SD11 may correspond to a “first shield electrode” in the present disclosure.

Furthermore, as illustrated in FIGS. 2 and 4, in Example Embodiment 1, the shield electrode SD12 connected to the ground terminal GND12 is disposed between the connection terminal P12 and the support electrode Wt1. The shield electrode SD12 has an L shape that extends from the ground terminal GND12 toward the negative side of the Y axis, and then bends about 90 degrees to extend toward the negative side of the X axis. The shield electrode SD12 may correspond to a “second shield electrode” in the present disclosure.

In this way, in Example Embodiment 1, the shield electrode SD11 is disposed between the connection terminal P11 and a portion of the support W1 (surfaces Wa1 and Wa2), the portion being located at a position closest to the connection terminal P11, on the main surface Sf1 in plan view as viewed from the negative side of the Z axis. In addition, in Example Embodiment 1, the shield electrode SD12 is disposed between the connection terminal P12 and a portion of the support W1 (surfaces Wa3 and Wa4), the portion being located at a position closest to the connection terminal P12, on the main surface Sf1 in plan view as viewed from the negative side of the Z axis.

Thus, in Example Embodiment 1, the shield electrode SD11 blocks direct capacitive coupling between the connection terminal P11 and the support electrode Wt1. In Example Embodiment 1, the shield electrode SD12 similarly blocks direct capacitive coupling between the connection terminal P12 and the support electrode Wt1. That is, in Example Embodiment 1, capacitive coupling of each of the connection terminals P11 and P12 with the support W1 can be reduced, and a decrease in the isolation between the connection terminals P11 and P12 due to the support W1 can be reduced.

In one example, either the shield electrode SD11 or SD12 need not be provided, and only one of the shield electrodes SD11 and SD12 may be provided. In another example, the shield electrode SD11 may be provided without a bent portion and may be disposed only between the connection terminal P11 and the surface Wa1. The shield electrode SD12 may similarly be provided without a bent portion and may be disposed only between the connection terminal P12 and the surface Wa3. That is, it is sufficient that at least one shield electrode is provided between either the connection terminal P11 or P12 and a portion of the support electrode Wt1 that is located in the closest position. This makes it possible to reduce a region in which the shield electrodes SD11 and SD12 are disposed while reducing a decrease in the isolation between the connection terminals P11 and P12, thus reducing costs.

Furthermore, in one example, the shield electrode SD11 may be connected to any one of the ground terminals GND11, GND12, and GND14, instead of to the ground terminal GND13. In another example, the shield electrode SD12 may be connected to any one of the ground terminals GND11, GND13, and GND14 instead of to the ground terminal GND12. For example, both of the shield electrodes SD11 and SD12 may be connected to the ground terminal GND13.

A trace Pt1 illustrated in FIG. 4 connects the connection terminal P11 and the functional element sr11. Of the surfaces Wa1 to Wa4, the surface that is disposed closest to the trace Pt1 is the surface Wa2. The shield electrode SD11 is also disposed between the trace Pt1 and the support electrode Wt1 (surface Wa2). In this way, in Example Embodiment 1, capacitive coupling between the support electrode Wt1 and the trace Pt1 can be reduced, to reduce or prevent a decrease in the isolation between the input and the output.

A trace Pt2 illustrated in FIG. 4 connects the connection terminal P12 and the functional element sr15. Of the surfaces Wa1 to Wa4, the surface that is disposed closest to the trace Pt2 is the surface Wa4. The shield electrode SD12 is disposed between the trace Pt2 and the support electrode Wt1 (surface Wa4). In this way, in Example Embodiment 1, capacitive coupling between the support electrode Wt1 and the trace Pt2 can be reduced.

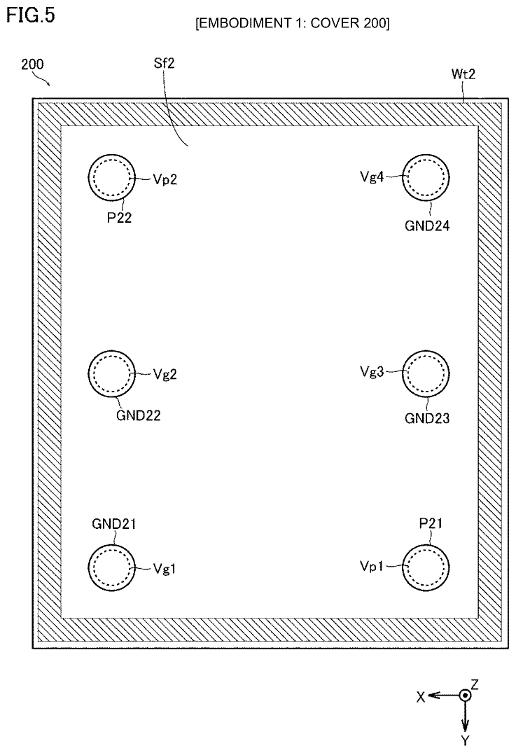

FIG. 5 is a plan view of the cover 200 taken along line II-II of FIG. 3. That is, FIG. 5 illustrates the main surface Sf2 as viewed from the hollow space Ar1. Connection terminals P21 and P22, ground terminals GND21 to GND24, and a support electrode Wt2 are disposed on the main surface Sf2. As illustrated in FIGS. 4 and 5, the connection terminals P21 and P22 are connected to the connection terminals P11 and P12, respectively, via the columnar electrodes Vp1 and Vp2. As illustrated in FIGS. 4 and 5, the ground terminals GND21 to GND24 are connected to the ground terminals GND11 to GND14, respectively, via the columnar electrodes Vg1 to Vg4. In FIGS. 4 and 5, the support wall Wp1 is not depicted.

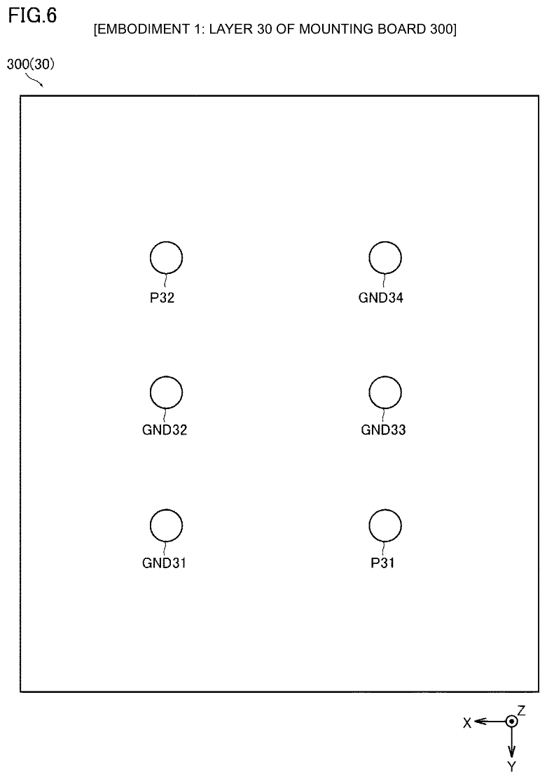

FIG. 6 is a diagram illustrating the layer 30 of the mounting board 300 as viewed from the positive side of the Z axis. That is, FIG. 6 illustrates a plan view of the layer 30 as viewed from the hollow space Ar1 side, as FIG. 5 does. The size of the mounting board 300 in the XY plane is larger than the sizes of the piezoelectric substrate 100 and the cover 200 in the XY plane.

The layer 30 includes connection terminals P31 and P32 and ground terminals GND31 to GND34 to electrically connect to components mounted to the mounting board 300 and terminals in the layer 50. The connection terminals P31 and P32 in FIG. 6 are connected to the connection terminals P21 and P22, respectively, in FIG. 5 via solder bumps, for example. The ground terminals GND31 to GND34 in FIG. 6 are connected to the ground terminals GND21 to GND24, respectively, in FIG. 5 via solder bumps, for example.

The layer 30 to the layer 50 of the mounting board 300 include wiring structures Cg1 to Cg4, Cp1, and Cp2. The wiring structure Cg1 connects the ground terminal GND31 to a ground electrode GG1, which will be described below. The wiring structure Cg2 connects the ground terminal GND32 to a ground electrode GG2, which will be described below. The wiring structure Cg3 connects the ground terminal GND33 to a ground electrode GG3, which will be described below. The wiring structure Cg4 connects the ground terminal GND34 to a ground electrode GG4, which will be described below. The wiring structure Cp1 connects the connection terminal P31 to the connection terminal P51. The wiring structure Cp2 connects the connection terminal P32 to a connection terminal P52.

FIG. 7 is a diagram illustrating the layer 40 of the mounting board 300 as viewed from the positive side of the Z axis. FIG. 7 illustrates a plan view of the layer 40 as viewed from the hollow space Ar1 side, as FIGS. 5 and 6 do. The layer 40 includes connection terminals P41A, P41B, P42A, and P42B, ground terminals GND41A and GND41B, ground terminals GND42A and GND42B, a ground terminal GND43, and ground terminals GND44A and GND44B. The connection terminals P41A and P42A in FIG. 7 are connected to the connection terminals P31 and P32, respectively, in FIG. 6 using via holes. The connection terminals P41A and P42A are disposed so that the connection terminals P31 and P32 lie on top of the connection terminals P41A and P42A, respectively, as viewed from the positive side of the Z axis.

The ground terminal GND41A, the ground terminal GND42A, the ground terminal GND43, and the ground terminal GND44A in FIG. 7 are connected to the ground terminal GND31, the ground terminal GND32, the ground terminal GND33, and the ground terminal GND34, respectively, in FIG. 6 using via holes. The ground terminal GND41A, the ground terminal GND42A, the ground terminal GND43, and the ground terminal GND44A are disposed so that the ground terminal GND31, the ground terminal GND32, the ground terminal GND33, and the ground terminal GND34 lie on top of the ground terminal GND41A, the ground terminal GND42A, the ground terminal GND43, and the ground terminal GND44A, respectively, as viewed from the positive side of the Z axis.

As illustrated in FIG. 7, except for the ground terminal GND43, the connection terminals P41A and P42A and the ground terminals GND41A, GND42A, and GND44A are connected to the connection terminals P41B and P42B and the ground terminals GND41B, GND42B, and GND44B, respectively, via traces Pp1, Pp2, Pg1, Pg2, and Pg4. The traces Pp1, Pp2, Pg1, Pg2, and Pg4 are portions of the wiring structures Cp1, Cp2, Cg1, Cg2, and Cg4, respectively.

As illustrated in FIG. 7, the trace Pg1 defines and functions as the inductor Lp11. The trace Pg2 defines and functions as the inductor Lp12. The trace Pg4 defines and functions as the inductor Lp14. Each of the traces Pg1, Pg2, and Pg4 has a unique inductance value.

Of the traces Pg1, Pg2, and Pg4, the trace Pg1 include the greatest number of turns and is also the longest in length. Thus, of the inductors Lp11, Lp12, and Lp14, the inductor Lp11 has the largest inductance value. The trace Pg2 has the same number of turns as the trace Pg4 and is shorter in length than the trace Pg4. Thus, of the inductors Lp11, Lp12, and Lp14, the inductor Lp12 has the smallest inductance value.

That is, the inductance values of the inductors Lp11, Lp12, and Lp14 increase in the order of the inductors Lp12, Lp14, and Lp11 (Lp12<Lp14<Lp11). In this way, the inductance values of the traces Pg1, Pg2, and Pg4 are individually set to obtain desired filter characteristics when the acoustic wave device 110 serves as the filter FLT in the acoustic wave module 1000 according to Example Embodiment 1.

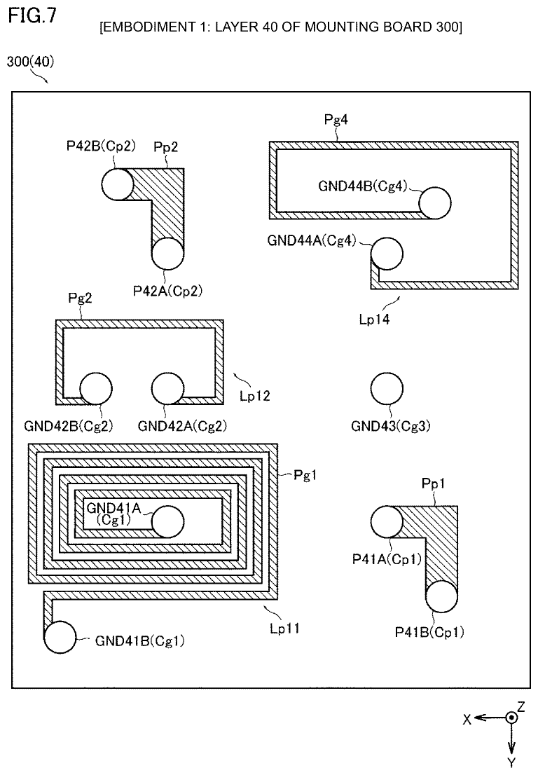

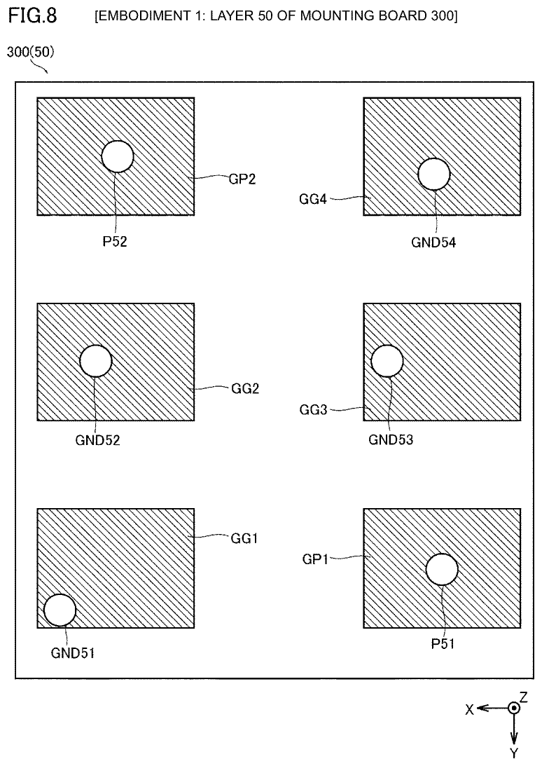

FIG. 8 is a diagram illustrating the layer 50 of the mounting board 300 as viewed from the positive side of the Z axis. That is, FIG. 8 illustrates a plan view of the layer 50 as viewed from the hollow space Ar1 side, as FIGS. 5 to 7 do.

The layer 50 includes connection terminals P51 and P52 and ground terminals GND51 to GND54. The connection terminals P51 and P52 in FIG. 8 are connected to the connection terminals P41B and P42B, respectively, in FIG. 7 using via holes. The connection terminals P51 and P52 are disposed so that the connection terminals P41B and P42B lie on top of the connection terminals P51 and P52, respectively, as viewed from the positive side of the Z axis.

The ground terminals GND51 to GND54 in FIG. 8 are connected to the ground terminal GND41B, the ground terminal GND42B, the ground terminal GND43, and the ground terminal GND44B, respectively, in FIG. 7 using via holes. The ground terminals GND51 to GND54 are disposed so that the ground terminal GND41B, the ground terminal GND42B, the ground terminal GND43, and the ground terminal GND44B lie on top of the ground terminals GND51 to GND54, respectively, as viewed from the positive side of the Z axis. In this way, terminals lying on top of each other define vias in the layer 30 to the layer 50.

The connection terminal P51 is an end portion of the wiring structure Cp1. The wiring structure Cp1 transmits a signal from the connection terminal P31 to the connection terminal P51. The connection terminal P52 is an end portion of the wiring structure Cp2. The wiring structure Cp2 transmits a signal from the connection terminal P32 to the connection terminal P52.

The wiring structure Cg1 transmits a signal from the ground terminal GND31 to the ground terminal GND51. The wiring structure Cg2 transmits a signal from the ground terminal GND32 to the ground terminal GND52.

The wiring structure Cg3 transmits a signal from the ground terminal GND33 to the ground terminal GND53. The ground terminal GND54 is an end portion of the wiring structure Cg4. The wiring structure Cg4 transmits a signal from the ground terminal GND34 to the ground terminal GND54.

As illustrated in FIG. 8, the connection terminals P51 and P52 are connected to connection electrodes GP1 and GP2 to connect to external components. The ground terminals GND51 to GND54 are connected to ground electrodes GG1 to GG4 to connect to external components. That is, the ground terminals GND51 to GND54 and the connection terminals P51 and P52 are disposed on the surface of the layer 50 on the negative side of the Z axis.

As described with reference to FIG. 7, the traces Pg1, Pg2, and Pg4 included in the layer 40 have inductance values that differ from each other to obtain desired filter characteristics when the acoustic wave device 110 serves as the filter FLT in the acoustic wave module 1000 according to Example Embodiment 1. That is, the wiring structures Cg1 to Cg4 in the mounting board 300 have inductance values that differ from each other. Some of the wiring structures Cg1 to Cg4 may have the same inductance value.

Of the wiring structures Cg1 to Cg4, the wiring structure Cg3, which includes no trace provided on the layer 40, has the smallest inductance value. Thus, taking into consideration the inductance values of the inductors Lp11, Lp12, and Lp14 described with reference to FIG. 7, of the wiring structures Cg1 to Cg4, the wiring structure Cg3 has the smallest inductance value, and the wiring structure Cg1 has the largest inductance value. In summary, the inductance values of the wiring structures Cg1 to Cg4 increase in the order of the wiring structure Cg3, the wiring structure Cg2, the wiring structure Cg4, and the wiring structure Cg1 (Cg3<Cg2<Cg4<Cg1).

For example, the inductance value of the wiring structure Cg3 is about 0.05 nH, the inductance value of the wiring structure Cg2 is about 0.3 nH, the inductance value of the wiring structure Cg4 is about 0.7 nH, and the inductance value of the wiring structure Cg1 is about 1.8 nH. Since the impedance increases as the inductance increases, the impedance of the wiring structures Cg1 to Cg4 also increase in the order of the wiring structure Cg3, the wiring structure Cg2, the wiring structure Cg4, and the wiring structure Cg1.

Returning to FIG. 4, as described above, the shield electrode SD11 is connected to the ground terminal GND13. The ground terminal GND13 is connected to the wiring structure Cg3, which has the smallest impedance. The shield electrode SD12 is connected to the ground terminal GND12. The ground terminal GND12 is connected to the wiring structure Cg2, which has the second smallest impedance after the wiring structure Cg3. In this way, in Example Embodiment 1, the shield electrodes SD11 and SD12 are connected to the wiring structures Cg3 and Cg2, respectively, which have smaller impedance than the wiring structures Cg1 and Cg4, among the plurality of wiring structures Cg1 to Cg4.

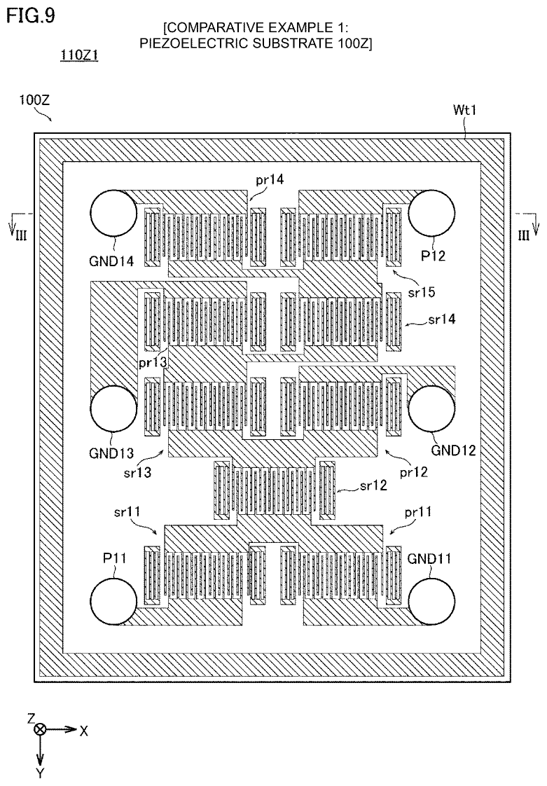

FIG. 9 is a plan view of a piezoelectric substrate 100Z according to Comparative Example 1. In Comparative Example 1, an acoustic wave device 110Z1 including the piezoelectric substrate 100Z will be described. The acoustic wave device 110Z1 has a configuration the same as or similar to the configuration of the acoustic wave device 110 according to Example Embodiment 1, except that the acoustic wave device 110Z1 has the piezoelectric substrate 100Z instead of the piezoelectric substrate 100. The piezoelectric substrate 100Z according to Comparative Example 1 has a configuration the same as or similar to the configuration of the piezoelectric substrate 100 according to Example Embodiment 1, except that neither the shield electrode SD11 nor the shield electrode SD12 is disposed on the main surface Sf1.

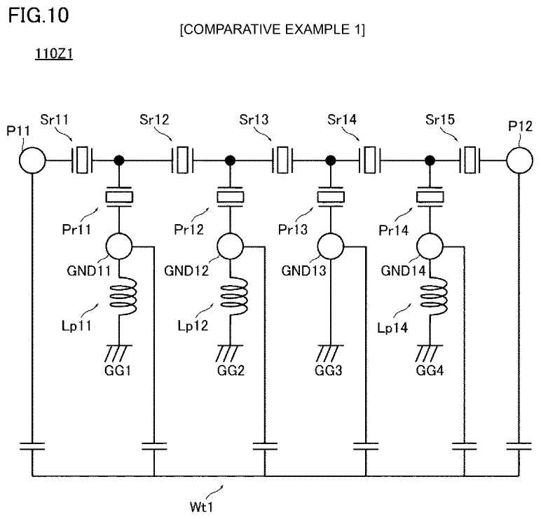

FIG. 10 is a diagram illustrating a circuit configuration of the acoustic wave device 11021 according to Comparative Example 1. As illustrated in FIG. 10, in Comparative Example 1, the shield electrode SD11 capacitively coupled to the connection terminal P11 and the shield electrode SD12 capacitively coupled to the connection terminal P12 are not provided. Thus, the support electrode Wt1 is capacitively coupled to the ground terminals GND11 to GND14 and the connection terminals P11 and P12. In other words, in Comparative Example 1, each of the connection terminals P11 and P12 is directly capacitively coupled to the support electrode Wt1. As a result, the connection terminal P11 is indirectly capacitively coupled to the connection terminal P12 via the support electrode Wt1, and the isolation between the connection terminal P11 and the connection terminal P12 is degraded. In FIG. 10, reference symbols for the wiring structures Cg1 to Cg4 are omitted.

More specifically, in Comparative Example 1, a signal flowing through a path passing through the series-arm resonators Sr11 to Sr15 is bypassed by indirect capacitive coupling between the connection terminal P11 and the connection terminal P12 via the support electrode Wt1, thereby affecting the characteristics of the series-arm resonators Sr11 to Sr15. As a result, in Comparative Example 1, the attenuation in a frequency range above the pass band on the high-frequency side may be degraded in the acoustic wave device 110Z1 serving as the filter FLT.

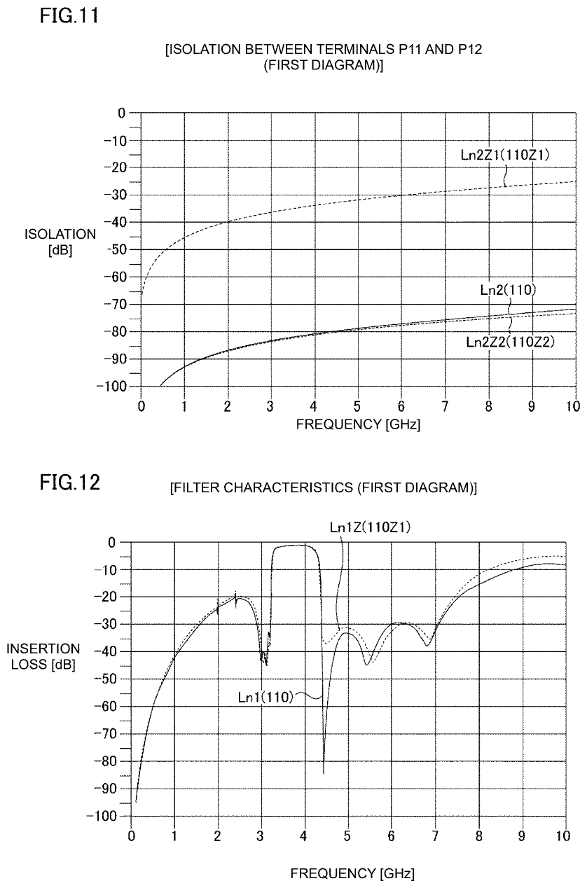

FIG. 11 is a first diagram for comparing the isolation between the connection terminals P11 and P12 in the acoustic wave devices 110 and 110Z1. The horizontal axis of the graph illustrated in FIG. 11 represents the frequency of a transmission signal, and the vertical axis represents the isolation between the connection terminals P11 and P12 of the acoustic wave device 110. A solid line Ln2 indicates the isolation between the connection terminals P11 and P12 in the acoustic wave device 110 according to Example Embodiment 1. A dashed line Ln2Z1 indicates the isolation between the connection terminals P11 and P12 in the acoustic wave device 110Z1 according to Comparative Example 1. A dashed line Ln2Z2 indicates the isolation between the connection terminals P11 and P12 in an acoustic wave device 110Z2 according to Comparative Example 2.

The acoustic wave device 110Z2 according to Comparative Example 2 in FIG. 11 has a configuration the same as or similar to the configuration of the acoustic wave device 110Z1 according to Comparative Example 1 except for the support W1. In the acoustic wave device 110Z2 according to Comparative Example 2, the support W1 is made of resin rather than metal. That is, the support W1 in the acoustic wave device 110Z2 according to Comparative Example 2 is not made of a conductor, and thus, capacitive coupling does not occur between the connection terminals P11 and P12 via the support W1 in Comparative Example 2.

As illustrated in FIG. 11, the acoustic wave device 110 according to Example Embodiment 1 has isolation characteristics equivalent or approximately equivalent to the isolation characteristics of the acoustic wave device 110Z2 according to Comparative Example 2. In contrast, the isolation characteristics of the acoustic wave device 110Z1 according to Comparative Example 1 are worse than the isolation characteristics of the acoustic wave device 110 according to Example Embodiment 1 and the acoustic wave device 110Z2 according to Comparative Example 2. In this way, since the shield electrodes SD11 and SD12 are provided, the isolation characteristics close to the isolation characteristics in Comparative Example 2 in which the support W1 is not made of a conductor are obtained in Example Embodiment 1. Furthermore, in Example Embodiment 1, since the support W1 is made of metal, it is possible to reduce or prevent moisture and the like entering the hollow space Ar1 from the outside.

FIG. 12 is a first diagram for comparing filter characteristics of acoustic wave devices. The horizontal axis of the graph illustrated in FIG. 12 represents the frequency of a transmission signal, and the vertical axis represents insertion loss. A solid line Ln1 indicates the insertion loss of the acoustic wave device 110 according to Example Embodiment 1 described with reference to FIGS. 3 to 8. A dashed line Ln1Z indicates the insertion loss of the acoustic wave device 110Z1 according to Comparative Example 1 described with reference to FIGS. 9 and 10.

The pass band of the acoustic wave device 110 according to Example Embodiment 1 is the first pass band (n77 band: about 3.3 GHZ to about 4.2 GHZ). The shield electrodes SD11 and SD12 cut a path that bypasses the series-arm resonators Sr11 to Sr15, and degradation of the characteristics of the series-arm resonators Sr11 to Sr15 is reduced, leading to an improved attenuation in the frequency range above the first pass band on the high-frequency side in the acoustic wave device 110 in Example Embodiment 1 compared with in Comparative Example 1, as illustrated in FIG. 12. That is, the attenuation in the vicinity of about 4.2 GHz is improved in Example Embodiment 1 compared with in Comparative Example in the example in FIG. 12. In this way, the passage of a signal in the second pass band can be reduced or prevented in a frequency range above the first pass band on the high-frequency side in the acoustic wave device 110 according to Example Embodiment 1, which defines and functions as the filter FLT for passing a signal in the first pass band.

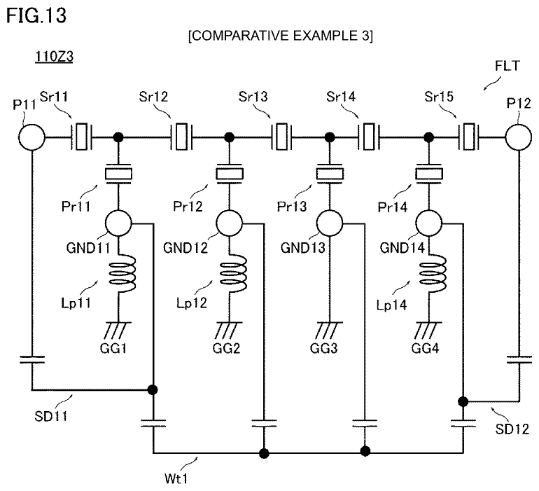

FIG. 13 illustrates a circuit configuration of an acoustic wave device 110Z3 according to Comparative Example 3. As illustrated in FIG. 13, the acoustic wave device 11023 according to Comparative Example 3 has a configuration the same as or similar to the configuration of the acoustic wave device 110 according to Example Embodiment 1, except that the ground terminals connected to the shield electrodes SD11 and SD12 are different. In FIG. 13, reference symbols for the wiring structures Cg1 to Cg4 are omitted.

Specifically, the shield electrode SD11 is connected to the ground terminal GND11 in the acoustic wave device 110Z3 according to Comparative Example 3, instead of the ground terminal GND13. The shield electrode SD12 is connected to the ground terminal GND14 in the acoustic wave device 11023 according to Comparative Example 3, instead of the ground terminal GND12.

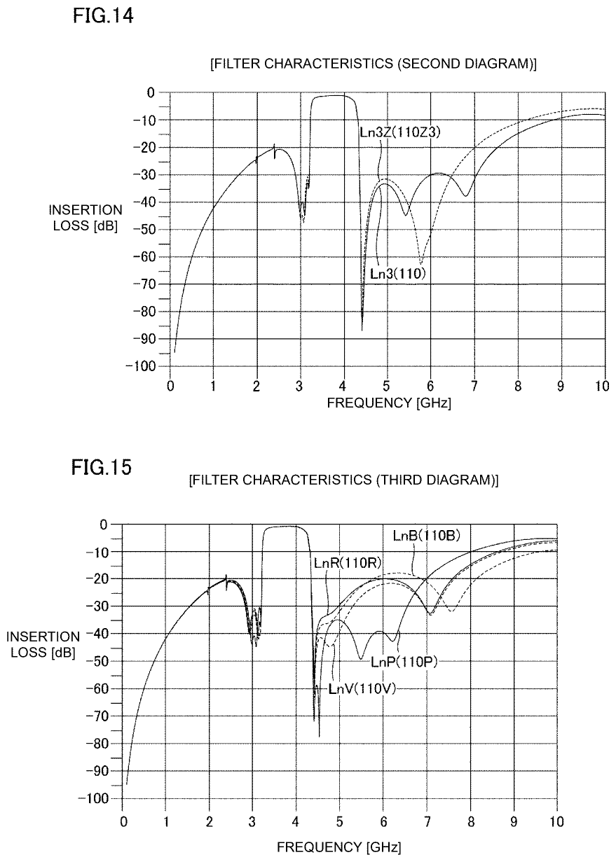

FIG. 14 is a second diagram for comparing filter characteristics of acoustic wave devices. A solid line Ln3 indicates the insertion loss of the acoustic wave device 110 according to Embodiment 1 similarly to the solid line Ln1 in FIG. 12. A dashed line Ln3Z indicates the insertion loss of the acoustic wave device 110Z3 according to Comparative Example 3.

The impedance of the wiring structure Cg1 including the ground terminal as an end portion is higher than the impedance of the wiring structure Cg3 including the ground terminal GND13 as an end portion. Thus, with reference to FIG. 2, if the shield electrode SD11 is connected to the ground terminal GND11, a signal transmitted from the connection terminal P11 to the shield electrode by capacitive coupling flows into the ground terminal GND11. Thereafter, the signal that has flowed into the ground terminal GND11 is less likely to flow into the ground electrode GG1 because of the inductor Lp11, leading to a higher proportion of the signal that flows into the parallel-arm resonator Pr11. As a result, the isolation between the connection terminals P11 and P12 is lower in Comparative Example 3 than in Example Embodiment 1.

The impedance of the wiring structure Cg4 including the ground terminal GND14 as an end portion is higher than the impedance of the wiring structure Cg2 including the ground terminal GND12 as an end portion. As in the case of the shield electrode SD11, a signal that has flowed into the ground terminal GND14 is less likely to flow into the ground electrode GG4 because of the inductor Lp14, which has an inductance value larger than the inductance value of the inductor Lp12, leading to a higher proportion of the signal that flows into the parallel-arm resonator Pr14. As a result, the isolation between the connection terminals P11 and P12 is lower in Comparative Example 3 than in Example Embodiment 1.

As illustrated in FIG. 14, the acoustic wave device 110 according to Example Embodiment 1 includes the shield electrodes SD11 and SD12 respectively connected to the ground terminals GND13 and GND12, which are the end portions of the wiring structures Cg3 and Cg2 having low impedance, thus leading to an improved attenuation in a frequency range above the first pass band on the high-frequency side (about 4.2 GHz to about 5.0 GHZ) compared with in Comparative Example 3.

FIG. 15 is a third diagram for comparing filter characteristics of acoustic wave devices. A solid line LnR indicates the insertion loss of an acoustic wave device 110R. A dashed line LnB indicates the insertion loss of an acoustic wave device 110B. A dashed line LnV indicates the insertion loss of an acoustic wave device 110V. A solid line LnP indicates the insertion loss of an acoustic wave device 110P.

Each of the acoustic wave devices 110R, 110B, 110V, and 110P has a configuration the same as or similar to the configuration of the acoustic wave device 110 according to Example Embodiment 1, except for the following points. The acoustic wave device 110R does not include the shield electrode SD12, but includes the shield electrode SD11 connected to the ground terminal GND11. The acoustic wave device 110B does not include the shield electrode SD11, but includes the shield electrode SD12 connected to the ground terminal GND12.

The acoustic wave device 110V does not include the shield electrode SD12, but includes the shield electrode SD11 connected to the ground terminal GND13. The acoustic wave device 110P does not include the shield electrode SD11, but includes the shield electrode SD12 connected to the ground terminal GND14.

With reference to FIG. 15, of the acoustic wave devices 110R, 110B, 110V, and 110P, the acoustic wave device 110V including the shield electrode SD11 connected to the wiring structure Cg3 having the smallest impedance has the most improved attenuation in the n79 band (about 4.4 GHZ to about 5.0 GHZ) in a frequency range above the first pass band (n77 band: about 3.3 GHZ to about 4.2 GHz) and in the 5.0 GHz band of Wi-Fi (registered trademark). The attenuation of the acoustic wave device 110P is worse than the attenuation of the acoustic wave device 110V in the frequency range from about 4.8 GHz to about 5.2 GHZ. In this way, the acoustic wave device 110 according to Example Embodiment 1 has an improved attenuation in a frequency range above the pass band on the high-frequency side because the shield electrode SD11 is connected to the wiring structure Cg3 having low impedance.

### Modification 1

In Example Embodiment 1, description has been provided with regard to the configuration in which the shield electrodes SD11 and SD12 are disposed on the main: surface Sf1 of the piezoelectric substrate 100. In Modification 1 of an example embodiment of the present invention, description will be provided with regard to a configuration in which a shield electrode is disposed on the main surface Sf2 of the cover 200 as well as on the main surface Sf1 of the piezoelectric substrate 100. In Modification 1, description will not be repeated with regard to components that are the same as or correspond to the components in the acoustic wave device 110 according to Example Embodiment 1.

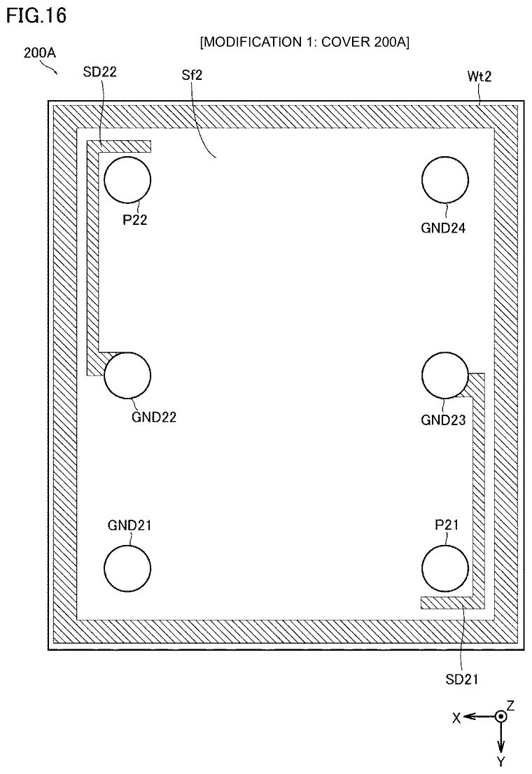

FIG. 16 is a plan view of a cover 200A according to Modification 1. As illustrated in FIG. 16, shield electrodes SD22 and SD21 are disposed on the main surface Sf2 of the cover 200A according to Modification 1. The shield electrode SD21 connected to the ground terminal GND23 is disposed between the connection terminal P21 and the support electrode Wt2. The shield electrode SD22 connected to the ground terminal GND22 is disposed between the connection terminal P22 and the support electrode Wt2. As a result, a decrease in the isolation between the connection terminal P21 and the connection terminal P22 can be reduced in Modification 1.

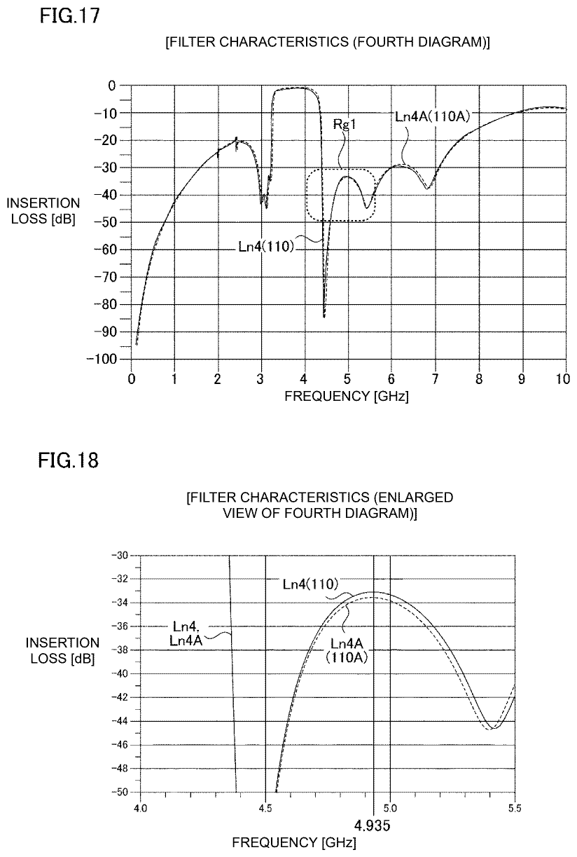

FIG. 17 is a fourth diagram for comparing filter characteristics of acoustic wave devices. A solid line Ln4 indicates the insertion loss of the acoustic wave device 110 according to Example Embodiment 1, similarly to the solid line Ln1 in FIG. 12. A dashed line Ln4A indicates the insertion loss of an acoustic wave device 110A according to Modification 1. In FIG. 17, a region Rg1 is indicated by a dashed line.

FIG. 18 is an enlarged view of the region Rg1 in FIG. 17. As illustrated in FIG. 18, an improved attenuation of the acoustic wave device 110A according to Modification 1 is observed in a band from about 4.5 GHZ to about 5.4 GHZ, which is in a frequency range above the first pass band on the high-frequency side. For example, the solid line Ln4 indicates about −33.110 dB, and the dashed line Ln4A indicates about −33.573 dB, at a frequency of about 4.935 GHZ.

As in Example Embodiment 1, the shield electrodes SD11 and SD12 are also disposed on the main surface Sf1 in Modification 1. In this way, a decrease in the isolation between the connection terminals P11 and P12 caused by the support W1 can also be reduced in the acoustic wave device 110A having a WLP structure in which the support W1 is made of metal in Modification 1.

In Modification 1, the connection terminal P21 may correspond to a “third connection terminal” in the present disclosure. The connection terminal P22 may correspond to a “fourth connection terminal” in the present disclosure. The shield electrode SD21 may correspond to a “third shield electrode” in the present disclosure. The ground terminal GND23 may correspond to a “third grounding terminal” in the present disclosure. The columnar electrode Vp1 may correspond to a “first electrode” in the present disclosure. The columnar electrode Vp2 may correspond to a “second electrode” in the present disclosure. The columnar electrode Vg3 may correspond to a “third electrode” in the present disclosure.

### Modification 2

In Example Embodiment 1, the connection terminals P11 and P12 and the ground terminals GND11 to GND14 are each disposed at the distance D2 from the support W1 having a frame shape on the main surface Sf1 illustrated in FIG. 4. In Modification 2 of an example embodiment of the present invention, description will be provided with regard to an example in which the ground terminals GND11 to GND14 are disposed at positions that differ from the positions in Example Embodiment 1. In Modification 2, description will not be repeated with regard to components that are the same as or correspond to the components in the acoustic wave device 110 according to Example Embodiment 1.

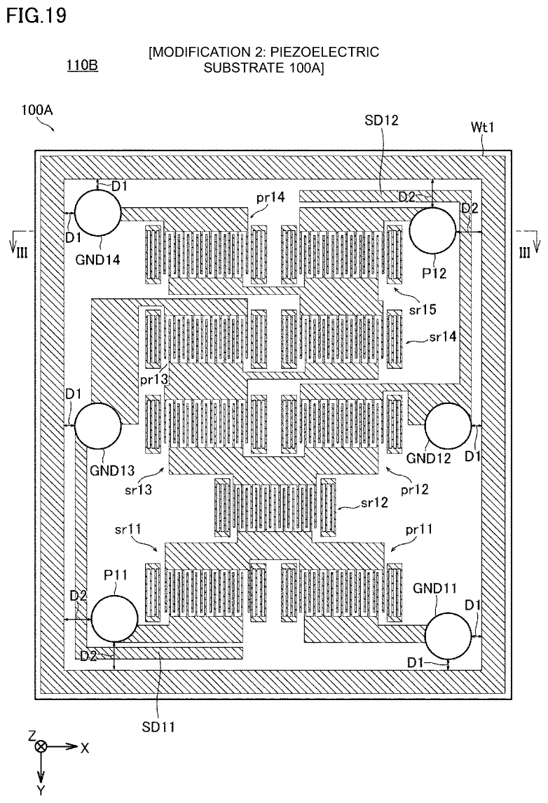

FIG. 19 is a plan view of a piezoelectric substrate 100A according to Modification 2. The acoustic wave device 110B according to Modification 2 includes the piezoelectric substrate 100A, which is illustrated in FIG. 19. As illustrated in FIG. 19, each of the ground terminals GND11 to GND14 is disposed at a distance D1 from the support W1 having a frame shape. The distance D1 is smaller than the distance D2.

In this way, a region where the functional elements pr11 to pr14 and sr11 to sr15 are disposed can be expanded in the hollow space Ar1 the acoustic wave device 110B according to in Modification 2. The connection terminals P11 and P12 need to be disposed further inside the hollow space Ar1 in Example Embodiment 1 than in Comparative Example 1 to allocate a region in which the shield electrodes SD11 and SD12 are disposed. However, since the ground terminals GND11 to GND14, as well as the shield electrodes SD11 and SD12, need not be disposed farther inside the hollow space Ar1, the ground terminals GND11 to GND14 in Modification 2 are disposed closer to the support electrode Wt1 than the connection terminals P11 and P12 are. In this way, it is possible to expand a region in which components such as functional elements can be disposed in the hollow space Ar1 in Modification 2.

The shield electrodes SD11 and SD12 are also disposed on the main surface Sf1 in Modification 2, as in Example Embodiment 1. In summary, a decrease in the isolation between the connection terminals P11 and P12 caused by the support W1 can also be reduced or prevented in the acoustic wave device 110B according to Modification 2 having a WLP structure in which the support W1 is made of metal.

### Modification 3

In Example Embodiment 1, description has been provided with regard to a configuration in which the shield electrodes SD11 and SD12 have thicknesses in the Z-axis direction close to the thicknesses of the functional elements. In Modification 3 of an example embodiment of the present invention, description will be provided with regard to a configuration in which the shield electrodes SD11 and SD12 have greater thicknesses in the Z-axis direction. In Modification 3, description will not be repeated with regard to components that are the same as or correspond to the components in the acoustic wave device 110 according to Example Embodiment 1.

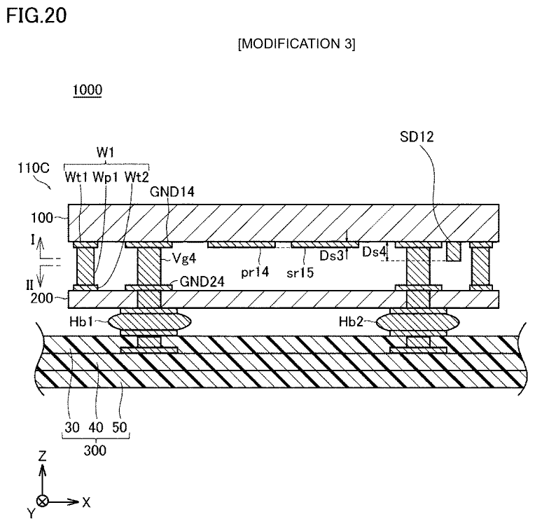

FIG. 20 is a cross-sectional view of the acoustic wave module 1000 including an acoustic wave device 110C according to Modification 3. In the acoustic wave device 110C according to Modification 3, the dimension (thickness) of the shield electrode SD12 in the Z-axis direction is equal or substantially equal to Ds4. In Modification 3, the dimension (thickness) of the shield electrode SD11 (not illustrated) in the Z-axis direction is also equal or substantially equal to Ds4, similarly to the dimension (thickness) of the shield electrode SD12.

In contrast, as illustrated in FIG. 20, the dimensions (thicknesses) of the functional elements pr14 and sr15 are equal or substantially equal to Ds3. In Modification 3, the dimensions (thicknesses) of the functional elements pr11 to pr13 and sr11 to sr14 (not illustrated) are also equal or substantially equal to Ds3, similarly to the dimensions (thicknesses) of the functional elements pr14 and sr15. Ds4 is greater than Ds3. In Modification 3, since the shield electrodes SD11 and SD12 are disposed in this way, capacitive coupling of the connection terminals P11 and P12 with the support electrode Wt1 can more reliably be reduced.

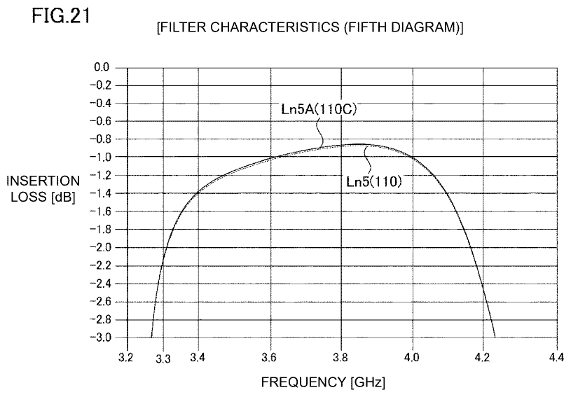

FIG. 21 is a fifth diagram for comparing filter characteristics of acoustic wave devices. A dashed line Ln5 indicates the insertion loss of the acoustic wave device 110 according to Example Embodiment 1, similarly to the solid line Ln1 in FIG. 12. A solid line Ln5A indicates the insertion loss of the acoustic wave device 110C according to Modification 3.

In FIG. 21, the solid line Ln5A indicates about −2.119 dB, and the dashed line Ln5 indicates about −2.129 dB, at a frequency of about 3.3 GHZ. The solid line Ln5A indicates about −2.537 dB, and the dashed line Ln5 indicates about −2.543 dB, at a frequency of about 4.2 GHZ. That is, resistance values of the inductive components of the shield electrodes SD11 and SD12 are smaller in Modification 3. In this way, the increases in the thicknesses of the shield electrodes SD11 and SD12 reduce the resistance values of the inductive components of the shield electrodes SD11 and SD12 in Modification 3, thus improving loss.

The shield electrodes SD11 and SD12 are also disposed on the main surface Sf1 in Modification 3, as in Example Embodiment 1. In this way, in Modification 3, a decrease in the isolation between the connection terminals P11 and P12 caused by the support W1 can also be reduced or prevented in the acoustic wave device 110C having a WLP structure in which the support W1 is made of metal.

### Modification 4

In Example Embodiment 1, description has been provided with regard to the configuration in which the acoustic wave device 110 is applied to the multiplexer 2. In Modification 4 of an example embodiment of the present invention, description will be provided with regard to a configuration in which the acoustic wave device 110 is applied to a communication apparatus 5. In Modification 4, description will not be repeated with regard to components that are the same as or correspond to the components in the acoustic wave device 110 according to Example Embodiment 1.

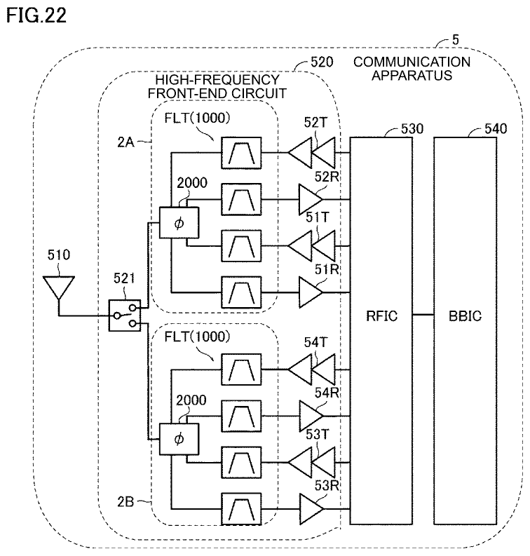

FIG. 22 is a block diagram of a communication apparatus 5 according to Modification 4. As illustrated in FIG. 22, the communication apparatus 5 includes an antenna element 510, a high-frequency front-end circuit 520, a radio frequency (RF) signal processing circuit 530, and a baseband integrated circuit (BBIC) 540.

The high-frequency front-end circuit 520 includes a switch 521, multiplexers 2A and 2B according to Example Embodiment 1, transmission amplifier circuits 51T to 54T, and reception amplifier circuits 51R to 54R. In the example in FIG. 22, each of the multiplexers 2A and 2B includes any one of the four acoustic wave devices 110 according to Example Embodiment 1 and

### Modifications 1 to 3.

The switch 521 is connected between the antenna element 510 and the multiplexer 2A, and is also connected between the antenna element 510 and the multiplexer 2B. The switch 521 chooses a multiplexer to which the antenna element 510 is to be connected from the multiplexer 2A and the multiplexer 2B and switches to the multiplexer.

The transmission amplifier circuits 51T and 52T are each a power amplifier that amplifies the power of a high-frequency signal from the RF signal processing circuit 530 in a predetermined frequency band and outputs an amplified signal to the multiplexer 2A. The transmission amplifier circuits 53T and 54T are each a power amplifier that amplifies the power of a high-frequency signal from the RF signal processing circuit 530 in a predetermined frequency band and outputs an amplified signal to the multiplexer 2B.

The reception amplifier circuits 51R and 52R are each a low-noise amplifier that amplifies the power of a high-frequency signal from the multiplexer 2A in a predetermined frequency band and outputs an amplified signal to the RF signal processing circuit 530. The reception amplifier circuits 53R and 54R are each a low-noise amplifier that amplifies the power of a high-frequency signal from the multiplexer 2B in a predetermined frequency band and outputs an amplified signal to the RF signal processing circuit 530.

The transmission amplifier circuits 51T and 52T and the reception amplifier circuits 51R and 52R are connected in parallel between the RF signal processing circuit 530 and the multiplexer 2A. The transmission amplifier circuits 53T and 54T and the reception amplifier circuits 53R and 54R are connected in parallel between the RF signal processing circuit 530 and the multiplexer 2B.

The RF signal processing circuit 530 processes high-frequency signals transmitted and high-frequency signals received by the antenna element 510. Specifically, the RF signal processing circuit 530 performs signal processing such as down-conversion to process a high-frequency signal that is input from the antenna element 510 via a receiving-side signal path and outputs a processed signal to the BBIC 540. The RF signal processing circuit 530 performs signal processing such as, for example, up-conversion to process a transmission signal that is input from the BBIC 540 and outputs a processed signal. In this way, the acoustic wave device 110 according to any one of Example Embodiment 1 and Modifications 1 to 3 can be applied to the communication apparatus 5 having the antenna element 510.

### Example Embodiment 2

In Example Embodiment 1, description has been provided with regard to the acoustic wave device 110 including the shield electrodes SD11 and SD12. In Example Embodiment 2 of the present invention, description will be provided with regard to an acoustic wave device 210 that includes neither the shield electrode SD11 nor the shield electrode SD12 and that includes the support electrode Wt1 connected to a ground terminal.

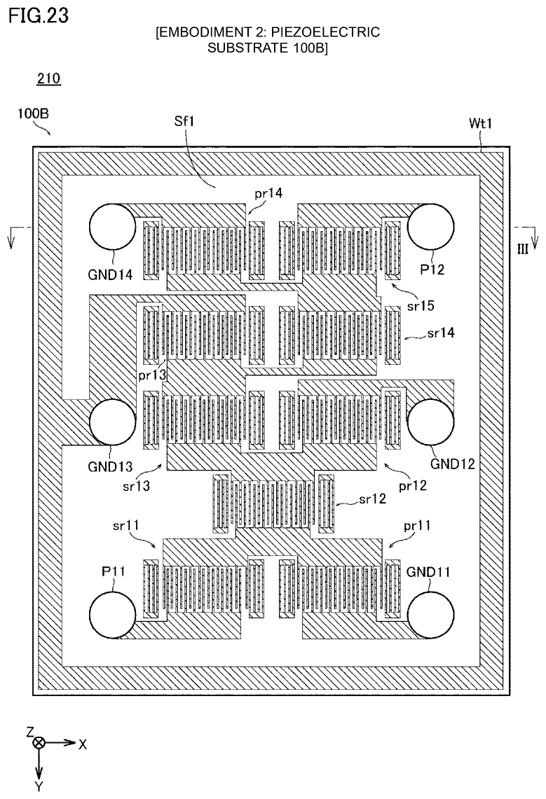

FIG. 23 is a plan view of a piezoelectric substrate 100B according to Example Embodiment 2. For the acoustic wave device 210 according to Example Embodiment 2, description will not be repeated with regard to components that are the same as or correspond to the components in the acoustic wave device 110 according to Example Embodiment 1. As illustrated in FIG. 23, the piezoelectric substrate 100B in the acoustic wave device 210 according to Example Embodiment 2 includes neither the shield electrode SD11 nor the shield electrode SD12 disposed on the main surface Sf1. The piezoelectric substrate 100B according to Example Embodiment 2 includes a support electrode Wt1 connected to a ground terminal GND13, instead of including the shield electrodes SD11 and SD12.

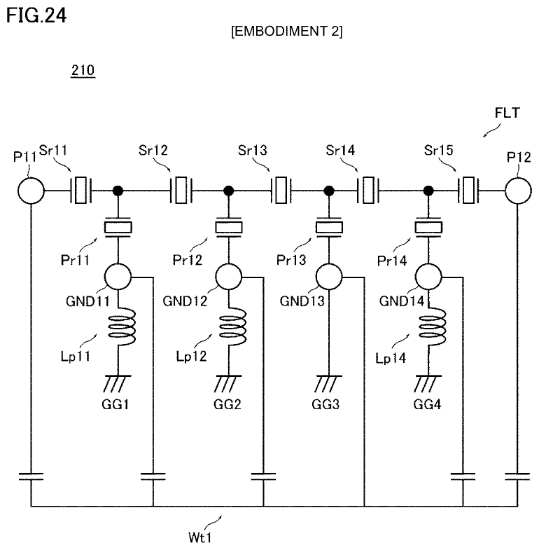

FIG. 24 illustrates a circuit configuration of the acoustic wave device 210 according to Example Embodiment 2. The acoustic wave device 210 according to Example Embodiment 2 has a configuration in which the capacitor between the support electrode Wt1 and the ground terminal GND13 is removed from the circuit diagram of Comparative Example 1 in FIG. 10 since the support electrode Wt1 is connected to the ground terminal GND13. In FIG. 24, reference symbols for the wiring structures Cg1 to Cg4 are omitted. In Example Embodiment 2, a signal transmitted from the connection terminal P11 to the support electrode Wt1 due to capacitive coupling between the connection terminal P11 and the support electrode Wt1 flows into the ground electrode GG3 via the ground terminal GND13. In this way, a decrease in the isolation between the connection terminals P11 and P12 can also be reduced or prevented in Example Embodiment 2.

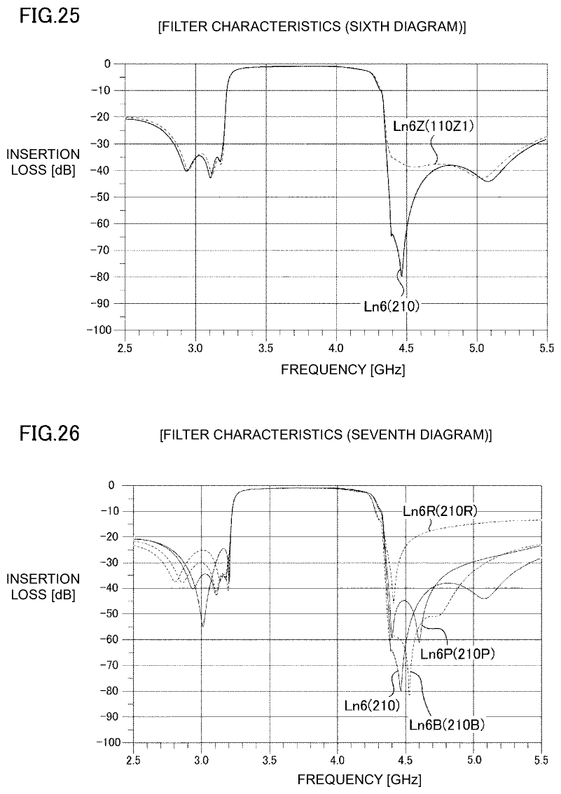

FIG. 25 is a sixth diagram for comparing filter characteristics of acoustic wave devices. A solid line Ln6 indicates the insertion loss of the acoustic wave device 210 according to Example Embodiment 2. A dashed line Ln6Z indicates the insertion loss of the acoustic wave device 11021 according to Comparative Example 1, similarly to the dashed line Ln1Z in FIG. 12. The acoustic wave device 11021 according to Comparative Example 1 includes neither the shield electrode SD11 nor the shield electrode SD12 and includes the support electrode Wt1 made of metal. In the acoustic wave device 110Z1 according to Comparative Example 1, the support electrode Wt1 is not connected to any of the ground terminals.

In Example Embodiment 2, the support electrode Wt1 is connected to the ground terminal GND13, thus cutting the path that bypasses the series-arm resonators Sr11 to Sr15, and the characteristics of the series-arm resonators Sr11 to Sr15 are maintained. In this way, the acoustic wave device 210 in Example Embodiment 2 has an improved attenuation in a frequency range above the first pass band on the high-frequency side as compared with in Comparative Example 1, as illustrated in FIG. 25. That is, in the example in FIG. 25, the attenuation is improved in the vicinity of 4.2 GHz in Example Embodiment 2 as compared with in Comparative Example. In this way, the passage of a signal in the second pass band can be reduced or prevented in a frequency range above the first pass band on the high-frequency side in the acoustic wave device 210 according to Example Embodiment 2, which defines and functions as the filter FLT for passing a signal in the first pass band.

FIG. 26 is a seventh diagram for comparing filter characteristics of acoustic wave devices. A solid line Ln6 indicates the insertion loss of the acoustic wave device 210, as in FIG. 25. A dashed line Ln6B indicates the insertion loss of an acoustic wave device 210B. A solid line Ln6P indicates the insertion loss of an acoustic wave device 210P. A dashed line Ln6R indicates the insertion loss of an acoustic wave device 210R.

Each of the acoustic wave devices 210R, 210B, and 210P has a configuration the same as or similar to the acoustic wave device 210 according to Example Embodiment 2, except for the following points. The support electrode Wt1 in the acoustic wave device 210R is connected to the ground terminal GND11 rather than to the ground terminal GND13. The support electrode Wt1 in the acoustic wave device 210B is connected to the ground terminal GND12 rather than to the ground terminal GND13. The support electrode Wt1 in the acoustic wave device 210P is connected to the ground terminal GND14 rather than to the ground terminal GND13.

With reference to FIG. 26, in the n79 band (about 4.4 GHz to about 5.0 GHZ), which is in a frequency range above the first pass band (n77 band: about 3.3 GHZ to about 4.2 GHZ), the attenuation is most improved for the acoustic wave device 210 including the support electrode Wt1 connected to the wiring structure Cg3 having the smallest impedance among the acoustic wave devices 210, 210R, 210B, and 210P. In this way, the acoustic wave device 210 according to Example Embodiment 2 includes the support electrode Wt1 connected to the wiring structure Cg3 having the smallest impedance, thus improving the attenuation in a frequency range above the pass band on the high-frequency side.

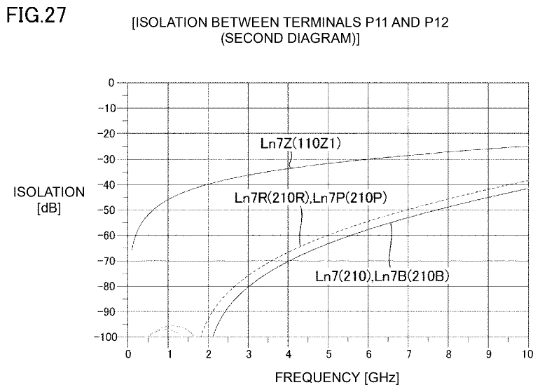

FIG. 27 is a second diagram for comparing the isolation between the connection terminals P11 and P12. A solid line Ln7Z indicates the isolation between the connection terminals P11 and P12 in the acoustic wave device 110Z1 according to Comparative Example 1.

A solid line Ln7Z indicates the isolation of the acoustic wave device 110Z1 according to Comparative Example 1. Dashed lines Ln7R and Ln7P indicate the isolation of the acoustic wave device 210R and the acoustic wave device 210P. As illustrated in FIG. 27, the dashed line Ln7R and the dashed line Ln7P overlap. Solid lines Ln7 and Ln7B indicate the isolation of the acoustic wave device 210 and the acoustic wave device 210B according to Example Embodiment 2. The solid line Ln7 and the solid line Ln7B overlap. In this way, in Example Embodiment 2, the most improved isolation characteristics are obtained for the acoustic wave devices 210 and 210B including the support electrodes Wt1 connected to the wiring structures Cg2 and Cg3, which have lower impedance than the wiring structures Cg1 and Cg4, among the wiring structures Cg1 to Cg4.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An acoustic wave device comprising:
a piezoelectric substrate including a first main surface;
a first connection terminal, a second connection terminal, and a first grounding terminal on the first main surface;
a functional element on the first main surface and configured to excite an acoustic wave to transmit a signal from the first connection terminal to the second connection terminal;
a first shield electrode on the first main surface and connected to the first grounding terminal;
a support on the first main surface around a region in which the first connection terminal, the second connection terminal, the first grounding terminal, the functional element, and the first shield electrode are located, and with a thickness in a direction normal to the first main surface; and
a cover supported by the support and located opposite to the piezoelectric substrate; wherein
the support includes metal;
the piezoelectric substrate, the support, and the cover define a hollow space, and the first connection terminal, the second connection terminal, the first grounding terminal, the functional element, and the first shield electrode are located in the hollow space; and
the first shield electrode is located between the first connection terminal and a portion of the support, the portion being located at a position closest to the first connection terminal, on the first main surface in plan view.

2. The acoustic wave device according to claim 1, wherein
the support has a frame shape and includes a first surface, a second surface, a third surface, and a fourth surface exposed to the hollow space;
the first surface faces the third surface;
the second surface faces the fourth surface; and
the first shield electrode is located between the first connection terminal and the first surface on the first main surface in plan view.

3. The acoustic wave device according to claim 2, wherein the first shield electrode is located between the first connection terminal and the second surface and between the first connection terminal and the first surface on the first main surface in plan view.

4. The acoustic wave device according to claim 1, further comprising:
a trace connecting the first connection terminal and the functional element; wherein
the first shield electrode is located between the trace and a portion of the support, the portion being located at a position closest to the trace, on the first main surface in plan view.

5. The acoustic wave device according to claim 2, further comprising:
a second grounding terminal on the first main surface; and
a second shield electrode on the first main surface and connected to the second grounding terminal; wherein
the second shield electrode is located between the second grounding terminal and a portion of the support, the portion being located at a position closest to the second grounding terminal, on the first main surface in plan view.

6. The acoustic wave device according to claim 5, wherein
the first surface faces the third surface; and
the second surface faces the fourth surface; and
on the first main surface in plan view, the first shield electrode is located between the first connection terminal and the first surface; and the second shield electrode is located between the second connection terminal and the third surface.

7. The acoustic wave device according to claim 6, wherein
on the first main surface in plan view, the first shield electrode is located between the first connection terminal and the second surface and between the first connection terminal and the first surface; and the second shield electrode is located between the second connection terminal and the fourth surface and between the second connection terminal and the third surface.

8. An acoustic wave module comprising:
the acoustic wave device according to claim 1; wherein
the acoustic wave module includes:
a mounting board to which the acoustic wave device is mounted; and
a connection component electrically connecting the acoustic wave device and the mounting board;
the acoustic wave device further includes a fourth grounding terminal on the first main surface and the first grounding terminal;
the mounting board includes:
a first wiring structure including one end connected to the first grounding terminal and an other end connected to a first grounding electrode; and
a second wiring structure including one end connected to the fourth grounding terminal and an other end connected to a second grounding electrode; and
an inductance value of the first wiring structure is smaller than an inductance value of the second wiring structure.

9. The acoustic wave module according to claim 8, wherein
the cover includes a second main surface facing the first main surface; and
the acoustic wave module includes:
a third connection terminal, a fourth connection terminal, and a third grounding terminal on the second main surface; and
a third shield electrode on the second main surface and connected to the third grounding terminal;
the third connection terminal is electrically connected to the first connection terminal via a first electrode;
the fourth connection terminal is electrically connected to the second connection terminal via a second electrode;
the third grounding terminal is electrically connected to the first grounding terminal via a third electrode; and
the third shield electrode is located between the third connection terminal and a portion of the support, the portion being located at a position closest to the third connection terminal, on the second main surface in plan view.

10. The acoustic wave module according to claim 8, wherein a distance between the first grounding terminal and a portion of the support located at a position closest to the first grounding terminal is less than a distance between the first connection terminal and the portion of the support located at the position closest to the first connection terminal.

11. The acoustic wave module according to claim 8, wherein a dimension of the first shield electrode in a direction normal to the piezoelectric substrate is larger than a dimension of the functional element in the direction normal to the piezoelectric substrate.

12. The acoustic wave module according to claim 8, wherein
the functional element includes an interdigital transducer (IDT) electrode; and
the piezoelectric substrate and the IDT electrode define a surface acoustic wave resonator.

13. The acoustic wave module according to claim 8, wherein the piezoelectric substrate includes aluminum nitride (AlN), lithium tantalate (LiTaO₃), or lithium niobate (LiNbO₃).

14. An acoustic wave module, comprising:
an acoustic wave device;
a mounting board to which the acoustic wave device is mounted; and
a connection component electrically connecting the acoustic wave device and the mounting board; wherein
the acoustic wave device includes:
a piezoelectric substrate including a first main surface;
a first connection terminal, a second connection terminal, a first grounding terminal, and a fourth grounding terminal on the first main surface;
a functional element on the first main surface and configured to excite an acoustic wave to transmit a signal to the first connection terminal and the second connection terminal;
a support on the first main surface around a region in which the first connection terminal, the second connection terminal, the first grounding terminal, the fourth grounding terminal, and the functional element are located, and with a thickness in a direction normal to the first main surface; and
a cover supported by the support and located opposite to the piezoelectric substrate; and
the support includes metal;
the piezoelectric substrate, the support, and the cover define a hollow space, and the first connection terminal, the second connection terminal, the first grounding terminal, the fourth grounding terminal, and the functional element are located in the hollow space;
the mounting board includes:
a first wiring structure including one end connected to the first grounding terminal and an other end connected to a grounding electrode; and
a second wiring structure including one end connected to the fourth grounding terminal and an other end connected to a grounding electrode;
an inductance value of the first wiring structure is smaller than an inductance value of the second wiring structure; and
the support is connected to the first grounding terminal.

15. A filter device comprising the acoustic wave device according to claim 1.

16. A filter device comprising the acoustic wave module according to claim 8.

17. A multiplexer comprising a plurality of filter devices including the filter device according to claim 15.

18. A multiplexer comprising a plurality of filter devices including the filter device according to claim 16.

19. A communication apparatus comprising:
the filter device according to claim 15;
an antenna element; and
an RF signal processing circuit to process a high-frequency signal transmitted and received by the antenna element.

20. A communication apparatus comprising:
the multiplexer according to claim 17;
an antenna element; and
an RF signal processing circuit to process a high-frequency signal transmitted and received by the antenna element.
